(19) United States
(12) Patent Application Publication
(10) Pub. No.: US 2010/0154874 A1
(43) Pub. Date: Jun. 24, 2010

(54) PHOTOELECTRIC CONVERSION DEVICE AND MANUFACTURING METHOD THEREOF

(76) Inventors: Takashi HIROSE, Isehara (JP); Riho KATAISHI, Atsugi (JP); Akihisa SHIMOMURA, Atsugi (JP)

Correspondence Address: ERIC ROBINSON, PMB 955, 21010 SOUTHBANK ST., POTOMAC FALLS, VA, 20165, US

(21) Appl. No.: 12/565,213

(22) Filed: Sep. 23, 2009

(30) Foreign Application Priority Data
Sep. 29, 2008 (JP) 2008-251170

(51) Int. Cl. H01L 31/18; H01L 31/00

(52) U.S. Cl. 136/255; 438/87; 257/E31.04; 438/93

(57) ABSTRACT

The oxidation of a lower electrode by the reaction between a metal element in the lower electrode and oxygen in a bonding layer is suppressed. The contamination of a semiconductor layer that is a photoelectric conversion layer by the diffusion of the metal element in the lower electrode into the semiconductor layer is suppressed. The invention relates to a photoelectric conversion device including a backside electrode layer, a crystalline semiconductor layer having a semiconductor junction, and a light-receiving-side electrode layer over a substrate having an insulating surface, in which the backside electrode layer has a stacked structure including a first conductive layer formed with a metal nitride or a refractory metal, a second conductive layer including aluminum (Al) or silver (Ag) as its main component, and a third conductive layer having low resistivity with a semiconductor material, and also relates to a manufacturing method thereof

### BACKGROUND OF THE INVENTION

1. Field of the Invention

The invention disclosed in this specification relates to a photoelectric conversion device formed with a crystalline semiconductor material and also relates to an electrode structure thereof.

2. Description of the Related Art

The industrial growth has been boosting energy consumption worldwide. Carbon dioxide is produced due to consumption of oil, coal, natural gas, and the like, which are mainly used as energy resources, and is said to be a factor of drastic global warming Therefore, photovoltaic power generation has been spreading for alternative energy in recent years.

For photovoltaic power generation, although solar heat may be utilized, mainly employed is a method of converting light energy into electric energy with use of the photoelectric characteristics of a semiconductor. Devices for converting light energy into electric energy are generally called photoelectric conversion devices (or photovoltaic devices, solar cells, or the like).

With the increase in production of photoelectric conversion devices as mentioned above, shortage of supply and rise of cost of raw material silicon, which is the material of single crystal silicon or polycrystalline silicon, have become significant problems for the industry. Although major silicon suppliers in the world have already tried to increase capability of silicon production, the increase in demand outweighs the capability and the shortage of supply does not seem to be solved for some time.

In the case of using crystalline silicon, a thickness of about 10 μm is enough for the thickness of a silicon thin film. However, a single crystal silicon wafer is generally manufactured with a thickness of from about 600 μm to about 800 μm, and a polycrystalline silicon wafer is generally manufactured with a thickness of from about 200 μm to about 350 μm. That is to say, the thickness of a single crystal silicon substrate or a polycrystalline silicon substrate is several tens of times as large as a thickness required to form a photoelectric conversion device and the raw material is not used efficiently. In view of this problem, it can be said that there is room for improvement in conventional photoelectric conversion devices.

As a manufacturing method of a thin film photoelectric conversion device, disclosed is a method for forming a photoelectric conversion element by implanting hydrogen ions into a single crystal silicon wafer, attaching a support substrate thereto, and performing heat treatment to separate a thin film silicon layer of a desired thickness from the single crystal silicon wafer at the hydrogen ion implanted portion (see Reference 1).

As another embodiment of a photovoltaic device formed using a single crystal semiconductor substrate, a photovoltaic device formed using a sliced single crystal semiconductor layer is given. For example, disclosed is a tandem solar cell in which hydrogen ions are implanted into a single crystal silicon substrate, a single crystal silicon layer which is separated from the single crystal silicon substrate in a layer shape is disposed over a support substrate in order to reduce the cost and save resources while maintaining high conversion efficiency (see Reference 2). In this tandem solar cell, the single crystal semiconductor layer and the substrate are bonded to each other with a conductive paste.

### REFERENCE

[Reference 1] Japanese Published Patent Application No. H10-093122
[Reference 2] Japanese Published Patent Application No. H10-335683

### SUMMARY OF THE INVENTION

As an insulating film that serves as a bonding layer, an insulating film containing oxygen, such as a silicon oxide film or an aluminum oxide film, is used. However, a problem arises in that oxygen contained in a glass substrate or a bonding layer reacts with a metal element of a lower electrode layer during heat treatment for separation and a metal film that is the lower electrode layer is oxidized.

This oxidation problem becomes a very significant issue particularly when a low-resistance, low-cost aluminum film or alloy film including aluminum is used as the metal film because aluminum has low heat resistance.

Furthermore, when heat treatment is performed while a lower electrode layer and a single crystal silicon layer are in contact with each other, depending on the kind of metal film used as the lower electrode layer, a metal element might diffuse into the single crystal silicon layer to contaminate the single crystal silicon layer, or the single crystal silicon layer which serves as an active layer might be eliminated by being alloyed to form a silicide.

An object of the present invention is to improve the thermal stability of a photoelectric conversion device formed with a crystalline semiconductor material.

Another object is to improve the reliability of an electrode in a photoelectric conversion device formed with a crystalline semiconductor material.

Therefore, in order to suppress the reaction between oxygen in a bonding layer and a metal element of a lower electrode layer, a first barrier film capable of blocking oxygen is formed between the lower electrode layer and the bonding layer. The first barrier film may be any film that has heat resistance and may have either a conductive property or an insulating property. When the first barrier film has a conductive property, the first barrier film functions as part of the lower electrode layer.

Furthermore, in order to suppress the reaction between a semiconductor layer, which is formed with a single crystal silicon layer or the like, and the lower electrode layer, a second barrier film is formed between the semiconductor layer and the lower electrode layer. The second barrier film may be any film that has a conductive property and is preferably a film having heat resistance.

Note that the semiconductor is not limited to silicon, and it is needless to say that the present invention can be applied to a semiconductor other than silicon, such as germanium or silicon germanium.

As the semiconductor, a single crystal semiconductor or a polycrystalline semiconductor can also be used. As a semiconductor substrate, a single crystal semiconductor substrate or a polycrystalline semiconductor substrate can be used, and a semiconductor layer formed by being separated from the semiconductor substrate can be a single crystal semiconductor layer or a polycrystalline semiconductor layer.

The ordinal numbers such as “first,” “second,” and “third” in this specification are used for convenience to distinguish elements and do not limit either the number of elements or the order of arrangement and steps.

The present invention relates to a photoelectric conversion device including a backside electrode layer, a crystalline semiconductor layer having a semiconductor junction, and a light-receiving-side electrode layer over a substrate having an insulating surface. The backside electrode layer has a stacked structure including a first conductive layer formed with a metal nitride or a refractory metal, a second conductive layer including aluminum (Al) or silver (Ag) as its main component, and a third conductive layer having low reactivity with a semiconductor material.

The first conductive layer is formed with any one of titanium nitride, tantalum nitride, and tungsten nitride.

The second conductive layer includes any one of aluminum containing scandium, neodymium, and titanium.

The third conductive layer includes any one of titanium nitride, tantalum nitride, tungsten, and molybdenum.

An insulating layer is provided between the substrate having an insulating surface and the first conductive layer.

The insulating layer includes silicon oxide.

The present invention also relates to a photoelectric conversion device including a backside electrode layer, a crystalline semiconductor layer having a semiconductor junction, and a light-receiving-side electrode layer over a substrate having an insulating surface. The backside electrode layer has a stacked structure including a first barrier layer capable of blocking oxygen, a metal layer, and a second barrier layer capable of suppressing the reaction between the crystalline semiconductor layer and the metal layer.

The first barrier layer includes any one of metal nitride, silicon nitride, and aluminum nitride.

The first barrier layer includes any one of titanium nitride, tantalum nitride, and tungsten nitride.

The metal film includes any one of aluminum containing scandium, aluminum containing neodymium, and aluminum containing titanium.

The second barrier layer includes any one of titanium nitride, tantalum nitride, tungsten, and molybdenum.

An insulating layer is provided between the substrate having an insulating surface and the first conductive layer.

The insulating layer includes silicon oxide.

The crystalline semiconductor layer having a semiconductor junction is a stacked layer including a p-type semiconductor layer, an intrinsic semiconductor layer, and an n-type semiconductor layer.

The present invention also relates to a method for manufacturing a photoelectric conversion device, including the steps of: forming an embrittled layer in a crystalline semiconductor substrate of one conductivity type; forming a backside electrode layer over the crystalline semiconductor substrate of one conductivity type;

forming an insulating layer over the backside electrode layer; bonding the crystalline semiconductor substrate of one conductivity type to a substrate having an insulating surface with the insulating layer interposed therebetween; separating the crystalline semiconductor substrate of one conductivity type along the embrittled layer to form a crystalline semiconductor layer; forming a semiconductor junction with the crystalline semiconductor layer; and forming a light-receiving-side electrode layer. The backside electrode layer is formed by sequentially stacking a first conductive layer having low reactivity with a semiconductor material, a second conductive layer including aluminum or silver as its main component, and a third conductive layer formed with a metal nitride or a refractory metal.

The present invention also relates to a method for manufacturing a photoelectric conversion device, including the steps of: forming an embrittled layer in a crystalline semiconductor substrate of one conductivity type; forming a backside electrode layer over the crystalline semiconductor substrate of one conductivity type;

forming an insulating layer over the backside electrode layer; bonding the crystalline semiconductor substrate of one conductivity type to a substrate having an insulating surface with the insulating layer interposed therebetween; separating the crystalline semiconductor substrate of one conductivity type along the embrittled layer to form a crystalline semiconductor layer; forming a semiconductor junction with the crystalline semiconductor layer; and forming a light-receiving-side electrode layer over the crystalline semiconductor layer. The backside electrode layer is formed by sequentially stacking a first barrier layer capable of blocking oxygen, a metal layer, and a second barrier layer capable of suppressing the reaction between the crystalline semiconductor layer and the metal layer.

The embrittled layer is formed by doping the crystalline semiconductor substrate of one conductivity type with hydrogen.

The substrate having an insulating surface and the insulating layer are disposed in close contact with each other and bonded to each other.

The reaction between oxygen in a bonding layer and a metal element of a lower electrode layer can be suppressed, and the oxidation of a metal film that is the lower electrode layer can be prevented.

In addition, the reaction between the semiconductor layer and the lower electrode layer can be suppressed, and the contamination or alloying of the semiconductor layer can be prevented.

### BRIEF DESCRIPTION OF THE DRAWINGS

FIGS. 1A to 1D are cross-sectional views illustrating a method for manufacturing a photoelectric conversion device.

FIGS. 2A to 2C are cross-sectional views illustrating a method for manufacturing a photoelectric conversion device.

FIGS. 3A to 3D are cross-sectional views illustrating a method for manufacturing a photoelectric conversion device.

FIG. 4 is a top view of a photoelectric conversion device.

FIGS. 5A to 5C are top views of semiconductor substrates.

FIG. 6 is a diagram illustrating a structure of an ion doping apparatus.

FIG. 7 is a cross-sectional TEM photograph of a photoelectric conversion device.

FIG. 8 is a cross-sectional TEM photograph of a photoelectric conversion device where a barrier film is not formed.

### DETAILED DESCRIPTION OF THE INVENTION

An embodiment of the present invention will be hereinafter described with reference to the accompanying drawings. Note that the present invention can be carried out in a variety of different modes, and it is easily understood by those skilled in the art that the modes and details of the present invention can be changed in various ways without departing from the spirit and scope thereof. Therefore, the present invention should not be interpreted as being limited to the description in the embodiment. Note that in the drawings given below, the same portions or portions having similar functions are denoted by the same reference numerals, and repetitive description thereof is omitted.

Note that in this specification, semiconductor devices refer to elements and devices in general which function by utilizing a semiconductor. Electric devices including electronic circuits, liquid crystal display devices, light-emitting devices, and the like and electronic devices mounted with these electric devices are included in the category of semiconductor devices.

### Embodiment 1

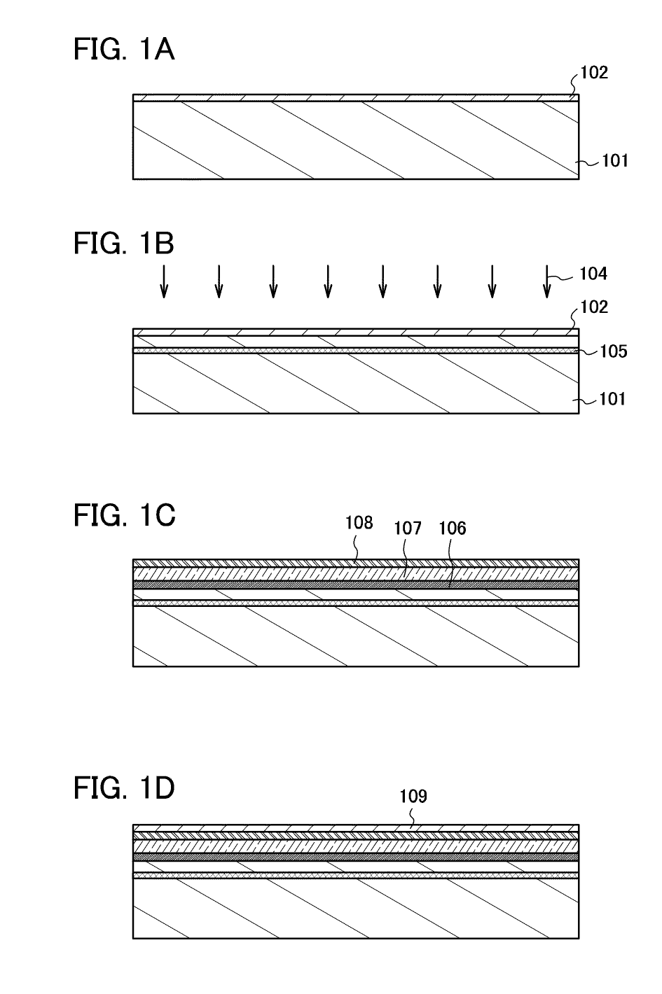

This embodiment is described with reference to FIGS. 1A to 1D, FIGS. 2A to 2C, FIGS. 3A to 3D, FIG. 4, FIGS. 5A to 5C, and FIG. 6.

As a semiconductor substrate 101, a crystalline semiconductor substrate such as a single crystal semiconductor substrate or a polycrystalline semiconductor substrate may be used. More specifically, a semiconductor wafer of silicon, germanium, or the like, a compound semiconductor wafer of gallium arsenide, indium phosphide, or the like can be used, for example. Among them, a single crystal silicon wafer is preferably used.

In this embodiment, an n-type single crystal silicon wafer is used as the semiconductor substrate 101. A first semiconductor layer 112 is separated from the semiconductor substrate 101 in a later step, and the semiconductor layer separated is used as an n-type semiconductor layer of a photoelectric conversion device; therefore, the semiconductor substrate 101 is preferably an n-type semiconductor substrate.

Although there is no particular limitation on the plan shape of the semiconductor substrate 101, the semiconductor substrate 101 is preferably rectangular when a support substrate 111 to which the semiconductor substrate 101 is fixed later is rectangular. A surface of the semiconductor substrate 101 is preferably mirror polished.

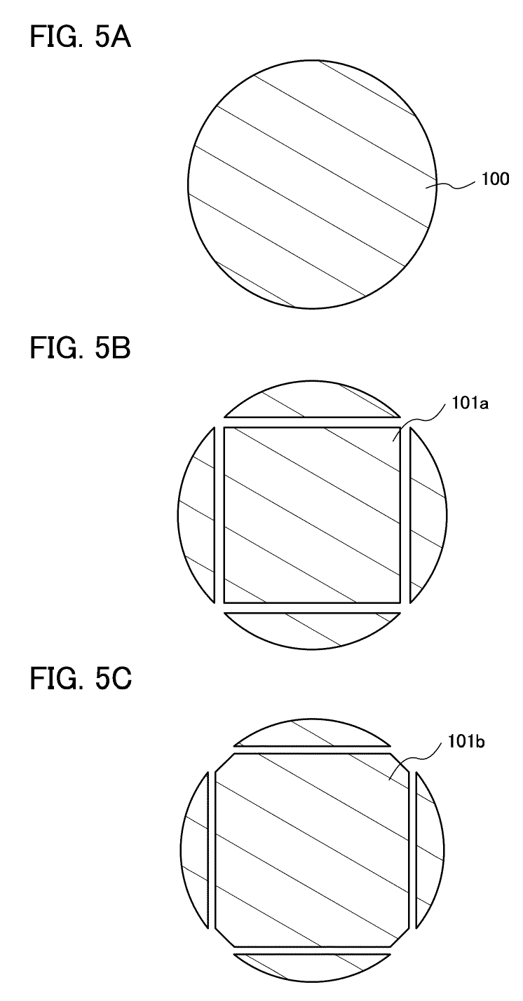

Note that although a circular semiconductor substrate may be used as the semiconductor substrate 101, it is more preferable that the circular semiconductor substrate be processed into a rectangular or polygonal shape. For example, a rectangular semiconductor substrate 101a (see FIG. 5B) or a polygonal semiconductor substrate 101b (see FIG. 5C) can be cut out of a circular semiconductor substrate 100 (see FIG. 5A).

Note that FIG. 5B illustrates the case where the rectangular semiconductor substrate 101a which is inscribed in the circular semiconductor substrate 100 is cut out to have a maximum area. Here, the angle of each corner of the semiconductor substrate 101a is about 90 degrees. FIG. 5C illustrates the case where the semiconductor substrate 101b is cut out so that the distance between the opposing lines is longer than that of the semiconductor substrate 101a. In this case, the angle of each corner of the semiconductor substrate 101b is not 90 degrees and the semiconductor substrate 101b has not a rectangular shape but a polygonal shape.

As illustrated in FIGS. 5A to 5C, the circular semiconductor substrate 100, the rectangular semiconductor substrate 101a, or the polygonal semiconductor substrate 101b may be used as the semiconductor substrate 101.

A protective layer 102 is formed over the semiconductor substrate 101 (see FIG. 1A). For the protective layer 102, silicon oxide or silicon nitride is preferably used. As a method for manufacturing the protective layer 102, a plasma CVD method, a sputtering method, or the like may be used, for example. Alternatively, the protective layer 102 can be formed by oxidation treatment of the semiconductor substrate 101 with an oxidizing chemical or oxygen radicals. Still alternatively, the protective layer 102 may be formed by oxidation of a surface of the semiconductor substrate 101 by a thermal oxidation method.

In this embodiment, the semiconductor substrate 101 is subjected to ozone water treatment, thereby forming a silicon oxide layer on the semiconductor substrate 101 as the protective layer 102.

With the protective layer 102, damage to a surface of the semiconductor substrate 101 due to the formation of an embrittled layer 105 in the semiconductor substrate 101 can be prevented.

Next, a surface of the protective layer 102 is irradiated with ions 104 to form the embrittled layer 105 in the semiconductor substrate 101 (see FIG. 1B). Here, as the ions 104, ions generated using a source gas containing hydrogen (in particular, H⁺, H₂⁺, H₃⁺, etc.) are preferably used. Note that the depth at which the embrittled layer 105 is formed is controlled by an acceleration voltage at the time of irradiation with the ions 104. Further, the thickness of the first semiconductor layer 112 to be separated from the semiconductor substrate 101 depends on the depth at which the embrittled layer 105 is formed.

In this embodiment, the embrittled layer 105 is formed by doping the semiconductor substrate 101 with hydrogen ions at an applied voltage of 80 kV with a dose of 2×10¹⁶ ions/cm².

The embrittled layer 105 may be formed at a depth of 500 nm or less, preferably 400 nm or less, and more preferably 50 nm to 300 nm from the surface of the semiconductor substrate 101. By forming the embrittled layer 105 at a small depth, a thick semiconductor substrate remains after the separation; therefore, the number of times the semiconductor substrate can be reused can be increased. Note that in the case where the embrittled layer 105 is formed at a small depth, the acceleration voltage is set low; thus, the productivity or the like should be considered.

The irradiation with the ions 104 can be performed using an ion doping apparatus or an ion implantation apparatus. Because an ion doping apparatus generally does not involve mass separation, even if the size of the semiconductor substrate 101 is increased, an entire surface of the semiconductor substrate 101 can be evenly irradiated with the ions 104.

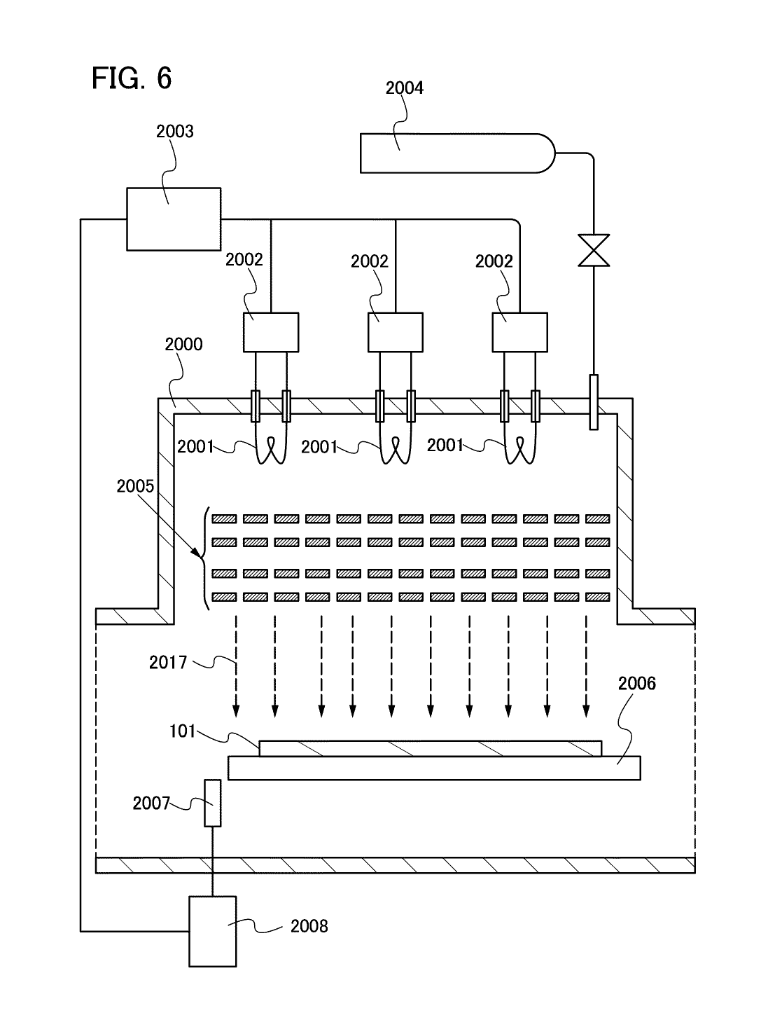

FIG. 6 illustrates an example of a structure of an ion doping apparatus. A source gas such as hydrogen is supplied from a gas supplying portion 2004 to an ion source 2000. Further, the ion source 2000 is provided with a filament 2001. A filament power source 2002 applies an arc discharge voltage to the filament 2001 to control the amount of electric current that flows to the filament 2001. The source gas supplied from the gas supplying portion 2004 is exhausted through an exhaustion system.

Hydrogen or the like supplied to the ion source 2000 is ionized by reacting with electrons discharged from the filament 2001. The ions 104 thus generated are accelerated through an extracting electrode 2005 to form an ion beam 2017. The semiconductor substrate 101 disposed on a substrate supporting portion 2006 is irradiated with the ion beam 2017. Note that the proportions of the kinds of the ions 104 included in the ion beam 2017 are measured with a mass spectrometer tube 2007 provided in the vicinity of the substrate supporting portion 2006. The results of measurement with the mass spectrometer tube 2007 are converted into signals in a mass spectrometer 2008 and fed back to a power source controlling portion 2003. Accordingly, the proportions of the kinds of the ions 104 can be controlled.

After the embrittled layer 105 is formed, the protective layer 102 is removed, and a second barrier film 106, a lower electrode 107, and a first barrier film 108 are sequentially formed over the semiconductor substrate 101 (see FIG. 1C). The second barrier film 106, the lower electrode 107, and the first barrier film 108 also function as a backside electrode layer of a photoelectric conversion device.

In this embodiment, the second barrier film 106 functions to suppress the reaction between the first semiconductor layer 112 and a metal element in the lower electrode 107. With the second barrier film 106, the contamination of the first semiconductor layer 112 by the diffusion of the metal element into the first semiconductor layer 112 can be prevented, and the elimination of the first semiconductor layer 112 by the alloying of the first semiconductor layer 112 to form a silicide can be prevented.

As the second barrier film 106, an electrically conductive nitride film of titanium nitride, tantalum nitride, or the like can be used. Alternatively, a metal film of tungsten, molybdenum, or the like, which is unlikely to diffuse into the first semiconductor layer 112 such as a single crystal silicon layer and has poor reactivity, may be used as the second barrier film 106. Note that as the second barrier film 106, a single layer film of the above film or a stacked-layer film of plural films may be used. In this embodiment, a titanium nitride film having a thickness of 25 nm is formed as the second barrier film 106.

The first barrier film 108 suppresses the oxidation of the lower electrode 107 which is caused by the reaction of oxygen in the support substrate 111 such as a glass substrate, or oxygen contained in a bonding layer 109, with the metal element of the lower electrode 107 during heat treatment for separation and transfer. The first barrier film 108 may be any film that has heat resistance and may have either a conductive property or an insulating property. When the first barrier film 108 has a conductive property, the first barrier film 108 functions as part of a lower electrode layer.

As the first barrier film 108, a variety of nitride films of titanium nitride, tantalum nitride, tungsten nitride, and the like can be used. Alternatively, a highly heat-resistant metal film of tungsten, molybdenum, nickel, or the like may be used. Note that as the first barrier film 108, a single layer film of the above film or a stacked-layer film of plural films may be used. In this embodiment, a titanium nitride film having a thickness of 25 nm is formed as the first barrier film 108.

When the second barrier film 106 and the first barrier film 108 are formed with metal films, the lower electrode 107 can be formed with a low-resistance, low-cost conductive material having low heat resistance. As such a conductive material, a conductive film including silver or aluminum as its main component, such as a film including aluminum containing neodymium (Al—Nd), a film including aluminum containing titanium (Al—Ti), or a film including aluminum containing scandium (Al—Sc), can be used. In this embodiment, an aluminum film having a thickness of 100 nm is formed as the lower electrode 107.

Next, the bonding layer 109 is formed with an insulator over the first barrier film 108 (see FIG. 1D). The bonding layer 109 may have a single layer structure or a stacked layer structure of two or more layers, and the bonding layer 109 is preferably formed with a thin film that has a smooth surface and is hydrophilic. The bonding layer 109 may be formed with an insulator such as silicon oxide. In this embodiment, a silicon oxide film is formed as the bonding layer 109.

As another method of forming the bonding layer 109, a CVD method such as a plasma CVD method, a photo-CVD method, or a thermal CVD method can be used. In particular, by employing a plasma CVD method, the bonding layer 109 which is smooth and has an average surface roughness (Rₐ) of 0.5 nm or less (preferably, 0.3 nm or less) can be formed.

Here, before a surface of the bonding layer 109 and a surface of the support substrate 111 that is a substrate having an insulating surface are bonded to each other, a bonding surface (in this embodiment, the surface of the bonding layer 109 and the surface of the support substrate 111) may be irradiated with an atomic beam or an ion beam. Alternatively, a bonding surface may be subjected to plasma treatment or radical treatment. By such treatment, the bonding surface can be activated, and favorable bonding can be performed. For example, a bonding surface can be activated by being irradiated with a neutral atomic beam or an ion beam of an inert gas such as argon, or a bonding surface can be activated by being exposed to oxygen plasma, nitrogen plasma, oxygen radicals, or nitrogen radicals. By activation of a bonding surface, substrates whose main components are different materials, like the bonding layer 109 that is an insulator and the support substrate 111 such as a glass substrate, can also form a bond through low-temperature treatment (e.g., 400° C. or lower). Further, a strong bond can be formed when a bonding surface is processed with ozone-added water, oxygen-added water, hydrogen-added water, pure water, or the like so that the bonding surface is made hydrophilic and the number of hydroxyls on the bonding surface is increased.

In this embodiment, after the bonding layer 109 is formed, the bonding layer 109 is subjected to argon plasma treatment to activate a bonding interface.

Next, the surface of the bonding layer 109 and the surface of the support substrate 111 are disposed close to each other and pressurized to bond a stacked structure including the semiconductor substrate 101 and the support substrate 111 to each other.

At this time, a bonding surface (here, the surface of the bonding layer 109 and the surface of the support substrate 111) are preferably cleaned sufficiently. This is because the possibility of defective bonding would increase in the presence of microscopic dust or the like on the bonding surface. Note that in order to reduce defective bonding, the bonding surface may be activated in advance. For example, one or both of bonding surfaces may be irradiated with an atomic beam or an ion beam so that the bonding surfaces can be activated. Alternatively, the bonding surfaces may be activated by plasma treatment, treatment with a chemical solution, or the like. Such activation of the bonding surface enables favorable bonding to be achieved even at a temperature of 400° C. or less.

Note that a structure may be employed in which a silicon insulating layer containing nitrogen, such as a silicon nitride layer or a silicon nitride oxide layer, is formed over the support substrate 111 and is closely attached to the bonding layer 109.

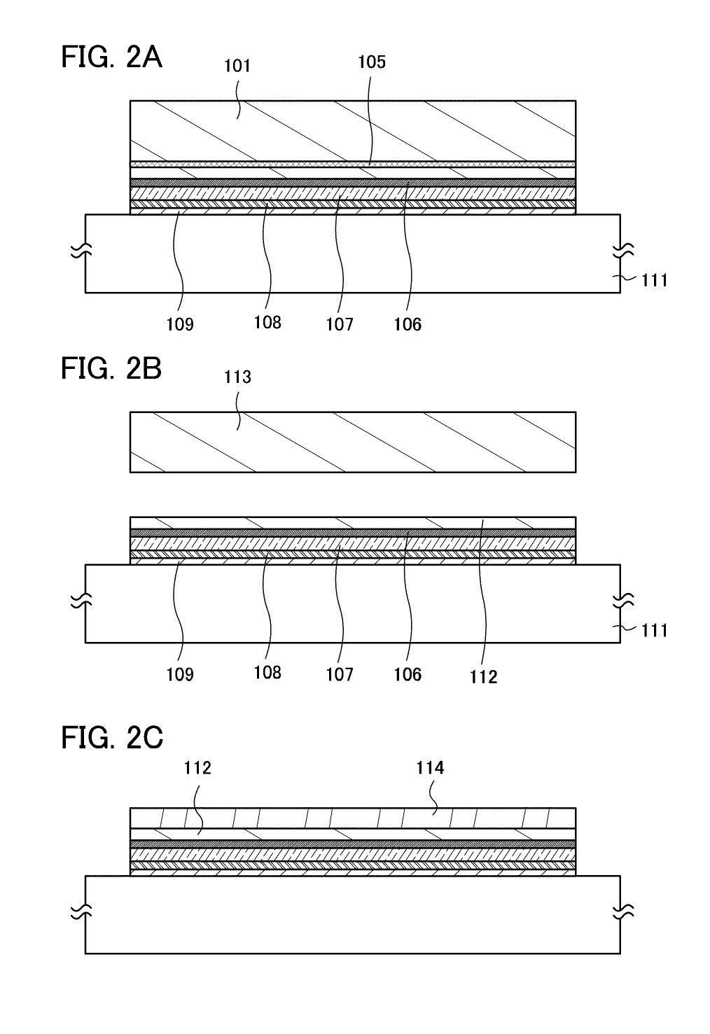

Next, heat treatment is performed to strengthen the bonding (see FIG. 2A). The temperature of the heat treatment should be set such that separation along the embrittled layer 105 is not promoted. For example, the temperature can be set lower than 400° C., preferably, lower than or equal to 300° C. The length of the heat treatment is not particularly limited and may be optimally set as appropriate depending on the relationship between processing speed and bonding strength. For example, heat treatment at about 200° C. for about two hours can be employed. Here, by irradiating only a bonding region with microwaves, local heat treatment can also be performed. Note that in the case where there is no problem with bonding strength, the heat treatment may be omitted. In this embodiment, the heat treatment is performed at 200° C. for two hours.

Next, the semiconductor substrate 101 is separated at the embrittled layer 105 into a separated substrate 113 and the first semiconductor layer 112 (see FIG. 2B). In other words, the first semiconductor layer 112 is transferred from the semiconductor substrate 101 to the support substrate 111. The separation of the semiconductor substrate 101 is performed by heat treatment. The temperature of the heat treatment for separation can be set based on the upper temperature limit of the support substrate 111. For example, in the case where a glass substrate is used as the support substrate 111, the heat treatment is preferably performed at a temperature of from 400° C. to 650° C. Note that the heat treatment may be performed at a temperature of from 400° C. to 700° C. for a short time. In this embodiment, the heat treatment is performed at 600° C. for two hours.

By performing heat treatment as described above, the volume of microvoids formed in the embrittled layer 105 is changed, and then the embrittled layer 105 is cracked. As a result, the semiconductor substrate 101 is separated along the embrittled layer 105. Because the bonding layer 109 is bonded to the support substrate 111, the first semiconductor layer 112 separated from the semiconductor substrate 101 remains over the support substrate 111. Further, because the bonding interface between the support substrate 111 and the bonding layer 109 is heated by this heat treatment, a covalent bond is formed at the bonding interface, so that the strength of the bonding between the support substrate 111 and the bonding layer 109 is further increased.

With the first barrier film 108, the reaction between oxygen in the bonding layer 109 and the metal element of the lower electrode 107 can be suppressed, and the oxidation of the lower electrode 107 that is a metal film can be prevented. In other words, a low-resistance, low-cost conductive material having low heat resistance can be used as a material of the lower electrode 107.

With the second barrier film 106, the reaction between the first semiconductor layer 112 to be separated from the semiconductor substrate 101 later and the lower electrode 107 can be prevented. Accordingly, the contamination of the first semiconductor layer 112 or the alloying of the first semiconductor layer 112 can be suppressed.

In this embodiment, an n-type single crystal silicon wafer is used as the semiconductor substrate 101, and thus the first semiconductor layer 112 is an n-type single crystal silicon layer. This layer is used as an n-type semiconductor layer of a solar cell.

Through the aforementioned steps, the first semiconductor layer 112 fixed to the support substrate 111 can be obtained. Note that the separated substrate 113 can be reused after reprocessing treatment. The separated substrate 113 that has been subjected to the reprocessing treatment may be used as a substrate for obtaining another first semiconductor layer 112 (corresponding to the semiconductor substrate 101 in this embodiment) or may be used for any other purposes. In the case where the separated substrate 113 which has been subjected to the reprocessing treatment is reused as a substrate for obtaining a first semiconductor layer 112, a plurality of photoelectric conversion devices can be manufactured from one semiconductor substrate 101.

Next, a second semiconductor layer 114 is formed over the first semiconductor layer 112 (see FIG. 2C). The second semiconductor layer 114 is formed by, for example, a vapor phase growth (vapor phase epitaxial growth) method. In this case, the second semiconductor layer 114 is formed using the first semiconductor layer 112 as a seed layer and is affected by the crystallinity of the first semiconductor layer 112. In this embodiment, the second semiconductor layer 114 is an intrinsic silicon layer and can be used as an intrinsic semiconductor layer of a solar cell.

Note that the “intrinsic semiconductor layer” herein refers to a semiconductor layer which contains an impurity imparting p-type or n-type conductivity at a concentration of 1×10²⁰ cm⁻³ or less and oxygen and nitrogen at a concentration of 9×10¹⁹ cm⁻³ or less and has photoconductivity 1000 times as high as dark conductivity. To the intrinsic semiconductor layer, boron (B) may be added at 10 ppm to 1000 ppm. In this specification, the intrinsic semiconductor layer is also called an i-type semiconductor layer.

In the case where a silicon layer is formed as the second semiconductor layer 114, it can be formed by a plasma CVD method using a mixed gas of a silane based gas (typically, silane) and a hydrogen gas as a source gas.

The source gas is a mixed gas in which the flow rate of a hydrogen gas is 50 or more times (preferably, 100 or more times) as high as the flow rate of a silane based gas. For example, a mixture of 4 sccm silane (SiH₄) and 400 sccm hydrogen may be used. By increasing the flow rate of a hydrogen gas, the second semiconductor layer 114 with higher crystallinity can be formed. Accordingly, hydrogen content in the second semiconductor layer 114 can be reduced.

Note that silane is not necessarily used as the silane based gas and disilane (Si₂H₆) or the like may alternatively be used. Further, a rare gas may be added to the source gas.

Note that before the epitaxial growth of the second semiconductor layer 114 is performed, a native oxide layer or the like formed on the surface of the first semiconductor layer 112 is preferably removed. This is because in the case where an oxide layer is present on the surface of the first semiconductor layer 112, epitaxial growth based on the crystallinity of the first semiconductor layer 112 cannot be promoted and thus the crystallinity of the second semiconductor layer 114 is degraded. Here, the oxide layer can be removed with a solution containing hydrofluoric acid or the like.

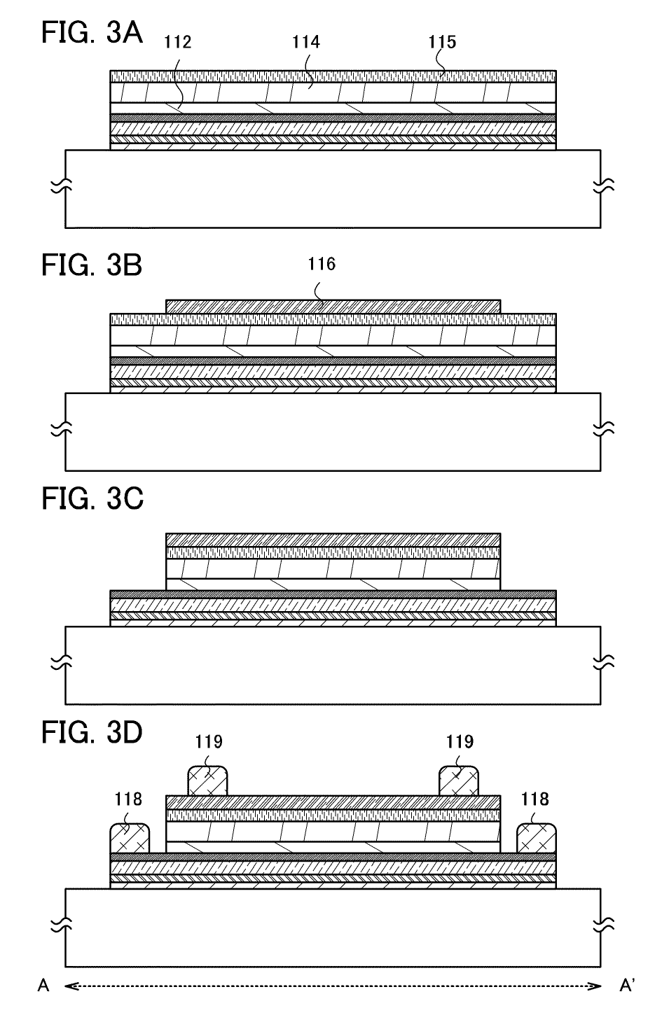

Next, a third semiconductor layer 115 is formed over the second semiconductor layer 114 (see FIG. 3A). Here, the third semiconductor layer 115 is formed using a material selected depending on the material of the second semiconductor layer 114. Also in that case, an oxide layer formed on the surface of the second semiconductor layer 114 is preferably removed in advance.

The third semiconductor layer 115 may also be formed by a vapor phase growth (vapor phase epitaxial growth) method. In the case where a silicon layer is formed as the third semiconductor layer 115, it can be formed by, for example, a plasma CVD method using a mixed gas of a silane based gas (typically, silane) and a hydrogen gas, and a gas containing an impurity element imparting p-type conductivity, such as diborane, as a source gas. Accordingly, the third semiconductor layer 115 is a p-type silicon layer and can be used as a p-type semiconductor layer of a solar cell.

Note that in this embodiment, an n-type single crystal silicon wafer is used as the semiconductor substrate 101, the first semiconductor layer 112 that is an n-type semiconductor layer is formed by being separated from the semiconductor substrate 101, and the third semiconductor layer 115 that is a p-type semiconductor layer is formed using a source gas containing an impurity element imparting p-type conductivity. However, the present invention is not limited to this embodiment. A semiconductor substrate containing an impurity element imparting p-type conductivity may be used as the semiconductor substrate 101. From this semiconductor substrate 101, a p-type semiconductor layer may be formed as the first semiconductor layer 112, and an n-type semiconductor layer may be formed as the third semiconductor layer 115 using a source gas containing an element imparting n-type conductivity, such as a source gas containing phosphine.

In the above manner, the first semiconductor layer 112, the second semiconductor layer 114, and the third semiconductor layer 115, which serve as a photoelectric conversion layer of a photoelectric conversion device, can be formed.

Next, an upper electrode 116 is formed over the third semiconductor layer 115 as a light-receiving-side electrode layer (see FIG. 3B). The upper electrode 116 may be formed using a light-transmitting conductive film. The upper electrode 116 can be formed by a sputtering method or a vacuum evaporation method. As the light-transmitting conductive film, a metal oxide film such as an indium tin oxide (ITO) film, an indium zinc oxide film, a zinc oxide film, or a tin oxide film may be used.

Next, the third semiconductor layer 115, the second semiconductor layer 114, and the first semiconductor layer 112 are etched using the upper electrode 116 as a mask to expose part of the second barrier film 106 (see FIG. 3C). Alternatively, the third semiconductor layer 115, the second semiconductor layer 114, the first semiconductor layer 112, and the second barrier film 106 may be etched to expose part of the lower electrode 107.

In this embodiment, the upper electrode 116 can be used as a mask. Thus, an etching mask does not need to be provided additionally. Needless to say, a mask may be formed using a resist or an insulating layer.

After that, an auxiliary electrode 118 that is electrically connected to the second barrier film 106 or the lower electrode 107 and an auxiliary electrode 119 that is electrically connected to the upper electrode 116 are formed (see FIG. 3D).

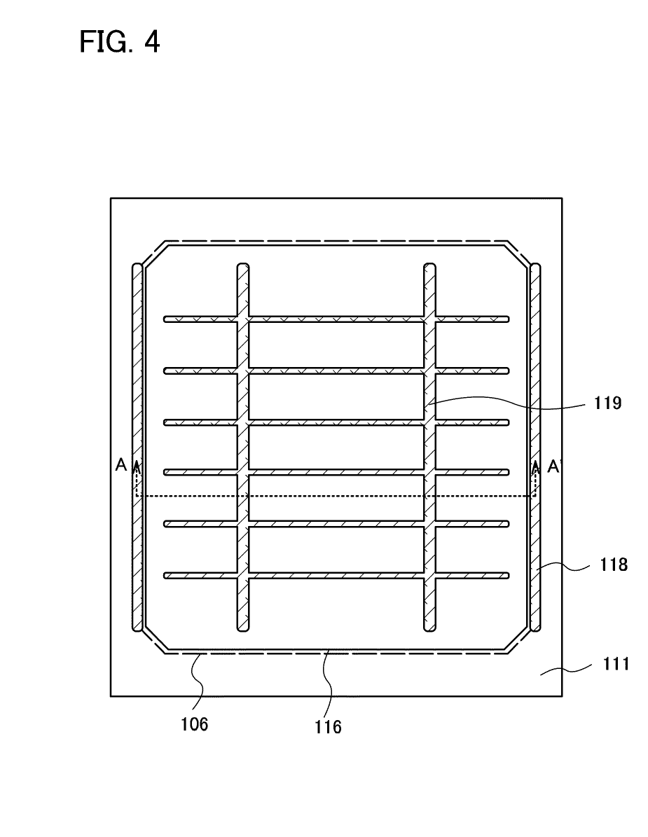

The auxiliary electrode 118 and the auxiliary electrode 119 are formed by screen printing with silver ink. As illustrated in FIG. 4, the auxiliary electrode 119 is formed into a grid shape (or a comb shape, a comb teeth shape) when seen from above. With such a shape, a solar cell can be irradiated with a sufficient amount of light and its light absorption efficiency can be improved. Through the above steps, a photoelectric conversion device that is a solar cell can be manufactured.

### Example 1

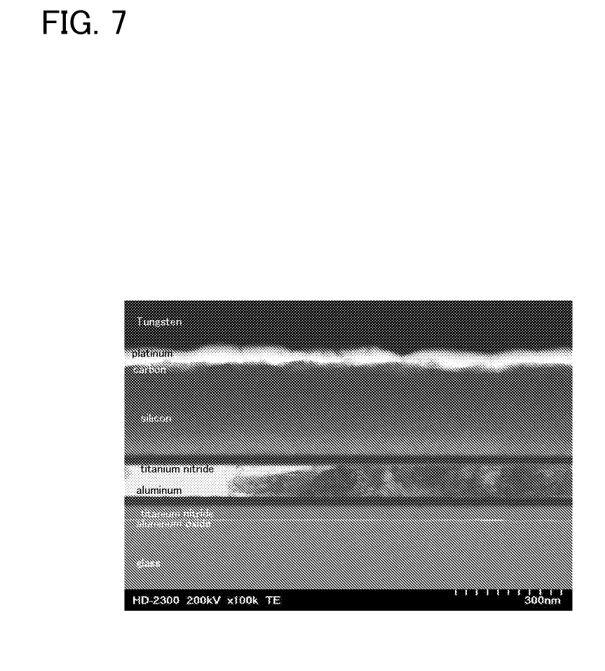

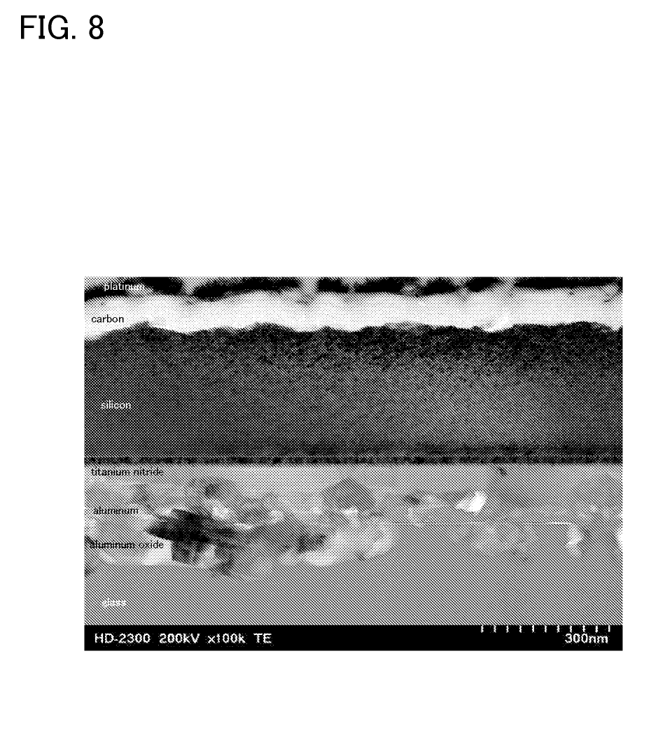

In this example, a cross-sectional transmission electron microscope (TEM) photograph of a photoelectric conversion device provided with an oxygen-blocking, heat-resistant film and that of a photoelectric conversion device not provided with an oxygen-blocking, heat-resistant film are described with reference to FIG. 7 and FIG. 8.

FIG. 7 is a cross-sectional TEM photograph of a photoelectric conversion device including a glass substrate as a support substrate, an aluminum oxide film as a bonding layer, a titanium nitride film as a barrier film, an aluminum film as a lower electrode, a titanium nitride film as a passivation film, and a silicon layer as a photoelectric conversion layer. In addition, a carbon film, a platinum film, and a tungsten film are formed over the silicon layer. The carbon film and the tungsten film are protective films formed to prevent a surface from being damaged during processing with a focused ion beam (FIB). The platinum film is formed to prevent charge buildup.

FIG. 8 is a cross-sectional TEM photograph of a photoelectric conversion device including a glass substrate as a support substrate, an aluminum oxide film as a bonding layer, no barrier film, an aluminum film as a lower electrode, a titanium nitride film as a passivation film, and a silicon layer as a photoelectric conversion layer. In addition, a carbon film and a platinum film are formed over the silicon layer. The carbon film is a protective film formed to prevent a surface from being damaged during processing with a focused ion beam (FIB). The platinum film is formed to prevent charge buildup.

The photoelectric conversion devices illustrated in FIG. 7 and FIG. 8 are each heated at 600° C. for two hours when the stacked structure including the silicon layer that is a photoelectric conversion layer, the aluminum film that is the lower electrode, and the aluminum oxide film that is a bonding layer is transferred to the glass substrate that is a support substrate.

In comparison with FIG. 7, in FIG. 8 where no barrier film is provided, the aluminum film that is a lower electrode is corroded by the aluminum oxide film that is a bonding layer. This means that in the heating step during transfer, oxygen in the aluminum oxide film that is a bonding layer reacts with the aluminum film that is a lower electrode to form aluminum oxide in the lower electrode.

Accordingly, it can be seen from this example that the barrier film suppresses the reaction between oxygen in the bonding layer and aluminum of the lower electrode.

This application is based on Japanese Patent Application serial no. 2008-251170 filed with Japan Patent Office on Sep. 29, 2008, the entire contents of which are hereby incorporated by reference.

What is claimed is:

1. A photoelectric conversion device comprising a backside electrode layer, a crystalline semiconductor layer having a semiconductor junction, and a light-receiving-side electrode layer over a substrate having an insulating surface,
wherein the backside electrode layer has a stacked structure including:
a first conductive layer comprises a material selected from the group consisting of a metal nitride and a refractory metal;
a second conductive layer comprises a material selected from the group consisting of aluminum and silver as a main component; and
a third conductive layer having low reactivity with a semiconductor material.

2. The photoelectric conversion device according to claim 1, wherein the first conductive layer is formed with any one of titanium nitride, tantalum nitride, and tungsten nitride.

3. The photoelectric conversion device according to claim 1, wherein the second conductive layer includes any one of aluminum containing scandium, neodymium, and titanium.

4. The photoelectric conversion device according to claim 1, wherein the third conductive layer includes any one of titanium nitride, tantalum nitride, tungsten, and molybdenum.

5. The photoelectric conversion device according to claim 1, further comprising an insulating layer between the substrate having the insulating surface and the first conductive layer.

6. The photoelectric conversion device according to claim 1, wherein the insulating layer includes silicon oxide.

7. The photoelectric conversion device according to claim 1, wherein the crystalline semiconductor layer having the semiconductor junction is a stacked layer including a p-type semiconductor layer, an intrinsic semiconductor layer, and an n-type semiconductor layer.

8. A photoelectric conversion device comprising a backside electrode layer, a crystalline semiconductor layer having a semiconductor junction, and a light-receiving-side electrode layer over a substrate having an insulating surface,
wherein the backside electrode layer has a stacked structure including:
a first barrier layer capable of blocking oxygen;
a metal layer; and
a second barrier layer capable of suppressing reaction between the crystalline semiconductor layer and the metal layer.

9. The photoelectric conversion device according to claim 8, wherein the first barrier layer includes any one of metal nitride, silicon nitride, and aluminum nitride.

10. The photoelectric conversion device according to claim 8, wherein the first barrier layer includes any one of titanium nitride, tantalum nitride, and tungsten nitride.

11. The photoelectric conversion device according to claim 8, wherein the metal film includes any one of aluminum containing scandium, aluminum containing neodymium, and aluminum containing titanium.

12. The photoelectric conversion device according to claim 8, wherein the second barrier layer includes any one of titanium nitride, tantalum nitride, tungsten, and molybdenum.

13. The photoelectric conversion device according to claim 8, further comprising an insulating layer between the substrate having the insulating surface and the first conductive layer.

14. The photoelectric conversion device according to claim 8, wherein the insulating layer includes silicon oxide.

15. The photoelectric conversion device according to claim 8, wherein the crystalline semiconductor layer having the semiconductor junction is a stacked layer including a p-type semiconductor layer, an intrinsic semiconductor layer, and an n-type semiconductor layer.

16. A method for manufacturing a photoelectric conversion device, comprising the steps of:
forming an embrittled layer in a crystalline semiconductor substrate of one conductivity type;
forming a backside electrode layer over the crystalline semiconductor substrate of one conductivity type;
forming an insulating layer over the backside electrode layer;
bonding the crystalline semiconductor substrate of one conductivity type to a substrate having an insulating surface with the insulating layer interposed therebetween;
separating the crystalline semiconductor substrate of one conductivity type along the embrittled layer to form a crystalline semiconductor layer;
forming a semiconductor junction with the crystalline semiconductor layer; and
forming a light-receiving-side electrode layer,
wherein the backside electrode layer is formed by sequentially stacking a first conductive layer having low reactivity with a semiconductor material, a second conductive layer including aluminum or silver as a main component, and a third conductive layer formed with a metal nitride or a refractory metal.

17. The method for manufacturing a photoelectric conversion device according to claim 16, wherein the embrittled layer is formed by doping the crystalline semiconductor substrate of one conductivity type with hydrogen.

18. The method for manufacturing a photoelectric conversion device according to claim 16, wherein the substrate having the insulating surface and the insulating layer are disposed in close contact with each other and bonded to each other.

19. A method for manufacturing a photoelectric conversion device, comprising the steps of:
forming an embrittled layer in a crystalline semiconductor substrate of one conductivity type;
forming a backside electrode layer over the crystalline semiconductor substrate of one conductivity type;
forming an insulating layer over the backside electrode layer;
bonding the crystalline semiconductor substrate of one conductivity type to a substrate having an insulating surface with the insulating layer interposed therebetween;
separating the crystalline semiconductor substrate of one conductivity type along the embrittled layer to form a crystalline semiconductor layer;
forming a semiconductor junction with the crystalline semiconductor layer; and
forming a light-receiving-side electrode layer over the crystalline semiconductor layer,
wherein the backside electrode layer is formed by sequentially stacking a first barrier layer capable of blocking oxygen, a metal layer, and a second barrier layer capable of suppressing reaction between the crystalline semiconductor layer and the metal layer.

20. The method for manufacturing a photoelectric conversion device according to claim 19, wherein the embrittled layer is formed by doping the crystalline semiconductor substrate of one conductivity type with hydrogen.

21. The method for manufacturing a photoelectric conversion device according to claim 19, wherein the substrate having the insulating surface and the insulating layer are disposed in close contact with each other and bonded to each other.
